(19) United States
(12) Patent Application Publication
(10) Pub. No.: US 2025/0275327 A1
(43) Pub. Date: Aug. 28, 2025

(54) HIGH EFFICIENT LED PIXEL ARRAY WITH COMPOSITE N-CONTACT

(71) Applicant: Lumileds LLC, San Jose, CA (US)

(72) Inventors: Toni Lopez, Vaals (NL); Erik William Young, San Jose, CA (US)

(73) Assignee: Lumileds LLC, San Jose, CA (US)

(21) Appl. No.: 18/585,451

(22) Filed: Feb. 23, 2024

(51) Int. Cl. H01L 27/15

(52) U.S. Cl. CPC H10H 29/142

(57) ABSTRACT

Arrays of light emitting diode (LED) devices in which each LED device includes a mesa having a top surface and at least one sidewall defining a trench having a bottom surface. The mesa comprises semiconductor layers including an n-type layer, an active layer, and a P-type layer, and an electrically conductive material fills the trench. An n-contact, which can be a transparent conductive oxide (TCO) layer, lines an entire surface of the sidewall and trench bottom, and a dielectric layer lines an entire length of the TCO layer, such that the dielectric layer optically isolates the trench and the n-contact functions as an n-contact and spreading layer.

### TECHNICAL FIELD

Embodiments of the disclosure generally relate to arrays of light emitting diode (LED) devices and methods of manufacturing the same. More particularly, embodiments are directed to arrays of light emitting diode devices in which a transparent conductive oxide (TCO) layer comprises an n-contact and spreading layer.

### BACKGROUND

A light emitting diode (LED) is a semiconductor light source that emits visible light when current flows through it. LEDs combine a P-type semiconductor with an N-type semiconductor. LEDs commonly use a III-V group compound semiconductor. A III-V group compound semiconductor provides stable operation at a higher temperature than devices that use other semiconductors. The III-V group compound is typically formed on a substrate formed of sapphire, silicon (Si), or silicon carbide (SiC).

In-organic light emitting diodes (i-LEDs) have been widely used to create different types of displays, LED matrices and light engines including automotive adaptive headlights, augmented-, virtual-, mix-reality (AR/VR/MR) headsets, smart glasses and displays for mobile phones, smart watches, monitors and TVs. The individual LED pixels in these architectures could have an area of few square millimetres down to few square micrometres depending on the matrix or display size and its pixel per inch requirements. One common approach is to create a monolithic array of LED pixels on an EPI wafer and later transfer and hybridize these LED arrays to a backplane to control individual pixels.

One embodiment of such monolithic arrays uses metal (e.g., Al- or Ag-based) side-contacts. These side-contacts serve as the electrical cathode for each pixel and also provide reflective sidewalls in between the pixels to reduce light scattering and propagation in lateral directions. An example of such LED arrays is shown in FIGS. 1-2. As shown in these figures, with this geometry a metal grid is created in between pixels of an LED display or matrix. These aluminum or silver side-contacts 16 are typically extended deep into the bottom of the trench 12 in between the pixels formed by etching and/or segmenting the semiconductor (epitaxial) layers and reach the substrate's surface.

Deep side contacts 16 can be used to ensure low sheet and contact resistance for cathode contacts, and to optically separate each LED pixel so that there is no optical crosstalk, thereby maximize optical contrast. There is, however, a cost of optical absorption due to the limited reflectivity of the metal contact. For example, since the trench 12 surface interface to the epitaxial layers (e.g., n-type layers 14, active region 13, p-type layers 15) must be a metal to form contact, optical efficiency (e.g., package efficiency, PE and extraction efficiency, ExE) can be limited by severe absorption in the cavity since metals are usually poor optical reflectors. A p-metal layer 17 may be formed on the p-type layers 15.

In many of these architectures, the substrate (e.g., sapphire, silicon) is removed after the LED array is integrated with the backplane controller to enhance light extraction and beam profiling. A standard approach to remove a sapphire substrate is by a laser lift-off process where a laser beam (UV laser in the case of a sapphire substrate) is used to detach the substrate from the epitaxial layers (e.g., n-type layers 14, active region 13, p-type layers 15, in this case, LED arrays grown on the substrate). Such methods could damage the side contacts, and such effects could also pose long-term reliability concerns.

Accordingly, there is a need for monolithic LED arrays and improved fabrication processes that improve optical efficiency.

### SUMMARY

One or more embodiments of the disclosure are directed to a light emitting diode (LED) device comprising a mesa comprising semiconductor layers, the semiconductor layers including an N-type layer, an active layer, and a P-type layer, the mesa having a top surface and at least one sidewall, the at least one sidewall defining a trench having a bottom surface; an electrically conductive material disposed in the trench; a p-type contact on the top surface of the mesa; an n-contact disposed between the electrically conductive material in the trench and the semiconductor layers; and an optical isolation layer disposed between the n-contact and the electrically conductive material, the optical isolation layer comprising a dielectric material; wherein the n-contact and optical isolation layer extend along an entire length of the at least one sidewall and bottom surface of the trench.

Another embodiment of the disclosure is directed to a light emitting diode (LED) array comprising a plurality of mesas defining pixels, each of the mesas comprising semiconductor layers, the semiconductor layers including an n-type layer, an active layer, and a p-type layer, each of the mesas having a top surface and sidewalls; a plurality of trenches, each of the trenches disposed between each of the mesas, each of the trenches having a bottom surface and opposing side surfaces defining the sidewalls of the mesas; an electrically conductive material disposed in each of the trenches; a p-type contact on the top surface of at least one mesa; an n-contact disposed along an entire length of the bottom surface of each of the trenches and along an entire length of the opposing side surfaces of each of the trenches, the n-contact disposed between the electrically conductive material and the semiconductor layers; and an optical isolation layer disposed along an entire length of the n-contact in at least one trench, the optical isolation layer disposed between the electrically conductive material and the n-contact in the least one trench, the optical isolation layer comprising a dielectric material.

Aspects of these embodiments can include one or more of the following features. The n-contact comprises a transparent conductive oxide layer. The transparent conductive oxide layer comprises zinc oxide. The dielectric layer comprises a material selected from the group consisting of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ). The dielectric layer comprises silicon oxide. The electrically conductive material comprises one or more of silver (Ag) and aluminum (AI). The LED device further comprises a light converting phosphor layer. The mesa further comprises a P-contact layer.

Another embodiment of the disclosure is directed to a display comprising the light emitting diode (LED) array affixed to a device substrate by anode metallization bumps. Aspects of this embodiment can include one or more of the following features. The pixels emit a single color. A first plurality of pixels is designed to emit a red color, a second plurality of pixels is designed to emit a blue color, and a third plurality of pixels is designed to emit a green color. the n-contact comprises a transparent conductive oxide layer. The transparent conductive oxide layer comprises zinc oxide. The dielectric layer comprises a material selected from the group consisting of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ). The dielectric layer comprises silicon oxide. The electrically conductive material comprises one or more of silver (Ag) and aluminum (Al). The LED device further comprises a light converting phosphor layer. The plurality of mesas defining pixels are configured to be individually operable.

Another embodiment of the disclosure is directed to a method of manufacturing a light emitting diode (LED) array comprising depositing a plurality of semiconductor layers on a substrate, the plurality of semiconductor layers including a p-type layer disposed on the substrate, an active layer disposed on the p-type layer, and an n-type layer disposed on an active layer; etching a portion of the semiconductor layers to form a plurality of trenches and a plurality of mesas defining a pixel, each of the mesas having a top surface and sidewalls, each of the trenches disposed between each of the mesas, each of the trenches having a bottom surface and opposing side surfaces defining the sidewalls of the mesas; depositing an n-contact on an entire length of the bottom surface of each of the trenches and along an entire length of the opposing side surfaces of each of the trenches; depositing a dielectric layer on an entire length of the n-contact in at least one trench; depositing an electrically conductive material in each of the trenches; and forming a p-type contact on the top surface of at least one mesa, wherein the dielectric layer optically isolates the at least one trench.

Aspects of this embodiment can include one or more of the following features. The n-contact comprises a transparent conductive oxide layer. The transparent conductive oxide layer comprises zinc oxide. The dielectric layer comprises a material selected from the group consisting of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ). The dielectric layer comprises silicon oxide. Depositing the n-contact further comprises depositing the n-contact on at least a portion of the top surface of the plurality of mesas, and wherein depositing the dielectric layer further comprises depositing the dielectric layer on an entire length of the n-contact on the top surface of the plurality of mesas. The method further comprises, prior to depositing the electrically conductive material in each of the trenches, removing at least a portion of the dielectric layer from the n-contact on the top surface of the plurality of mesas to expose a portion of the n-contact on the top surface of the plurality of mesas. Depositing the electrically conductive material in each of the trenches further comprises depositing the electrically conductive material on the n-contact and dielectric layer on the top surface of the plurality of mesas, and the method further comprises planarizing the electrically conductive material prior to forming the p-type contact. Planarizing the electrically conductive material removes the electrically conductive material, the transparent conductive oxide layer, and dielectric layer from the top surface of the plurality of mesas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a perspective view of a conventional LED pixel with full metal trench sidewalls according to the prior art;

FIG. 2 illustrates a cross-sectional view of the LED pixel of FIG. 1 according to the prior art;

FIGS. 3A-3M illustrate cross-sectional views of a portion of an LED device during a method of manufacture according to one or more embodiments;

FIG. 4 illustrates a top view of a portion of a pixel LED die with n-contact formation at the pixel corners according to one or more embodiments;

FIG. 5A illustrates a top perspective view of a portion of a pixel LED die with self-aligned n-contact formation at the pixel corners according to one or more embodiments;

FIG. 5B illustrates a bottom perspective view of the pixel LED die of FIG. 5A;

FIG. 5C illustrates a bottom view of an LED array with four pixel LED die of FIG. 5A according to one or more embodiments;

FIG. 6 illustrates a schematic of a portion of a monolithic LED pixel array with side-wall cathode contact according to one or more embodiments;

FIG. 7 illustrates a process flow diagram for a method of manufacturing an LED device according to one or more embodiments;

FIG. 8 illustrates a top plan view of an exemplary display device according to one or more embodiments; and

FIG. 9 schematically illustrates an exemplary display system comprising LED devices according to embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN and alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Reference to a micro-LED (uLED) means a light emitting diode having one or more characteristic dimensions (e.g., height, width, depth, thickness, etc. dimensions) of less than 100 micrometers. In one or embodiments, one or more dimensions of height, width, depth, thickness have values in a range of 1 to 100 micrometers, including all values and subranges therebetween.

LEDs capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a growth substrate such as a sapphire, silicon carbide, III-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

The disclosure provides a die/epi/converter layout for creating monolithic micro-LED arrays, Mini-LEDs, and LED arrays with increased optical performance. The materials and structure provide significant improvements in the optical performance of state-of-the-art monolithically integrated micro-LED or LED arrays. The methods and devices are applicable to both phosphor-converted and direct-color LEDs where each individual pixel has an area ranging from few hundred square micrometres (Micro-LEDs) to square millimetres (conventional LEDs).

Embodiments herein describe LED devices and methods for forming LED devices. In particular, the present disclosure describes arrays of LED devices in which a transparent conductive oxide (TCO) layer is employed as an n-contact and spreading layer. According to embodiments of the disclosure, pixels are formed with full trenches of composite materials that enable both low optical absorption and optical isolation across near neighbouring pixels. Embodiments of the disclosure offer significant advantages in optical efficacy (Im/W).

The embodiments of the disclosure are described by way of the Figures, which illustrate devices (e.g., LEDs) and processes for forming devices in accordance with one or more embodiments of the disclosure. The processes shown are merely illustrative possible uses for the disclosed processes, and the skilled artisan will recognize that the disclosed processes are not limited to the illustrated applications.

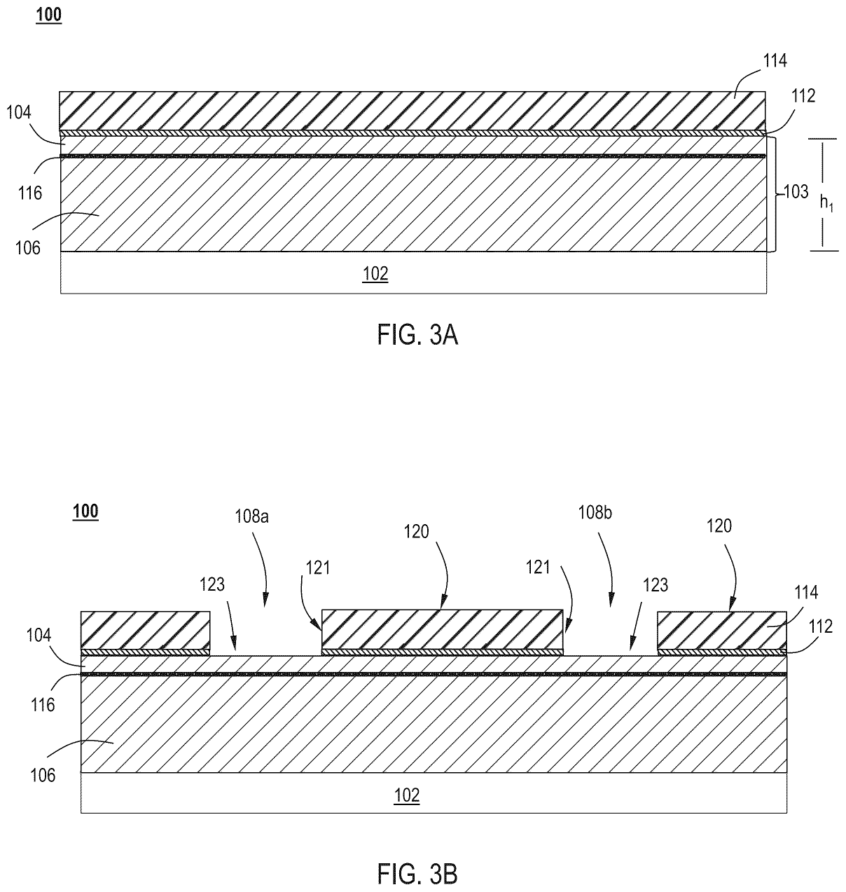

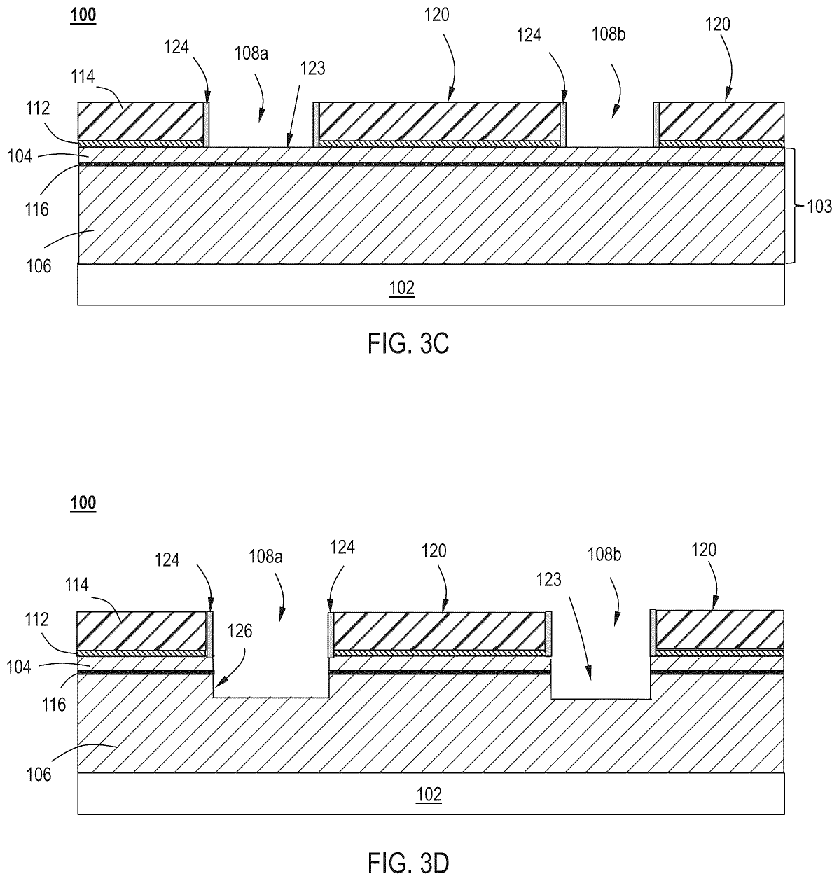

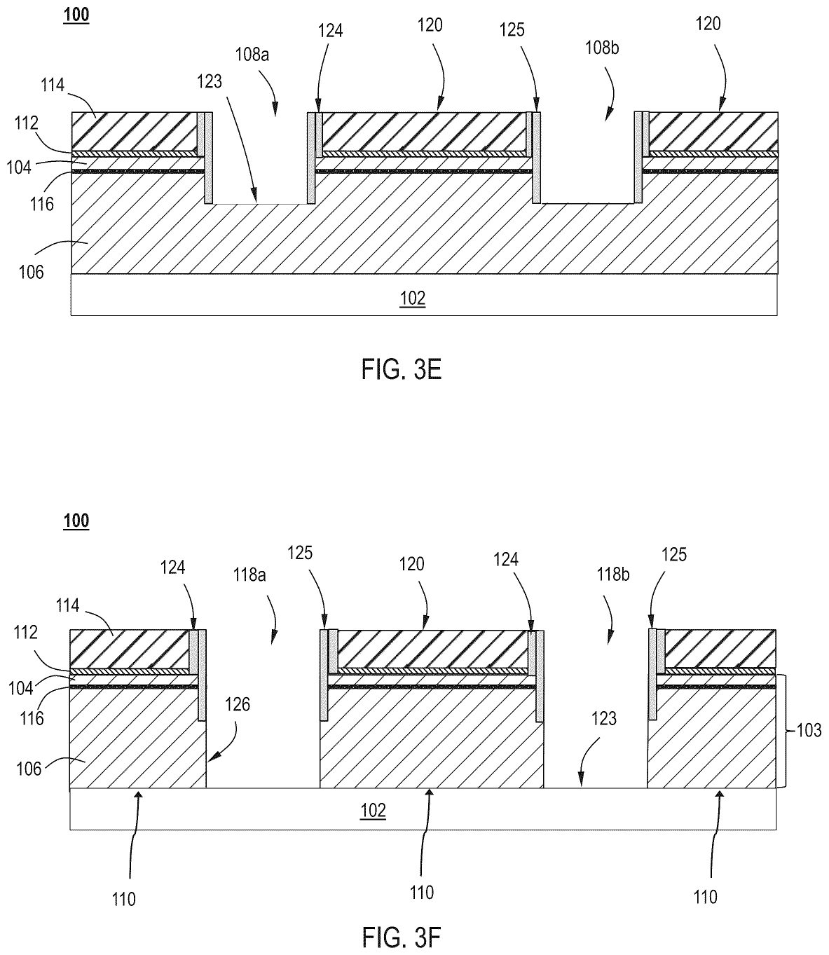

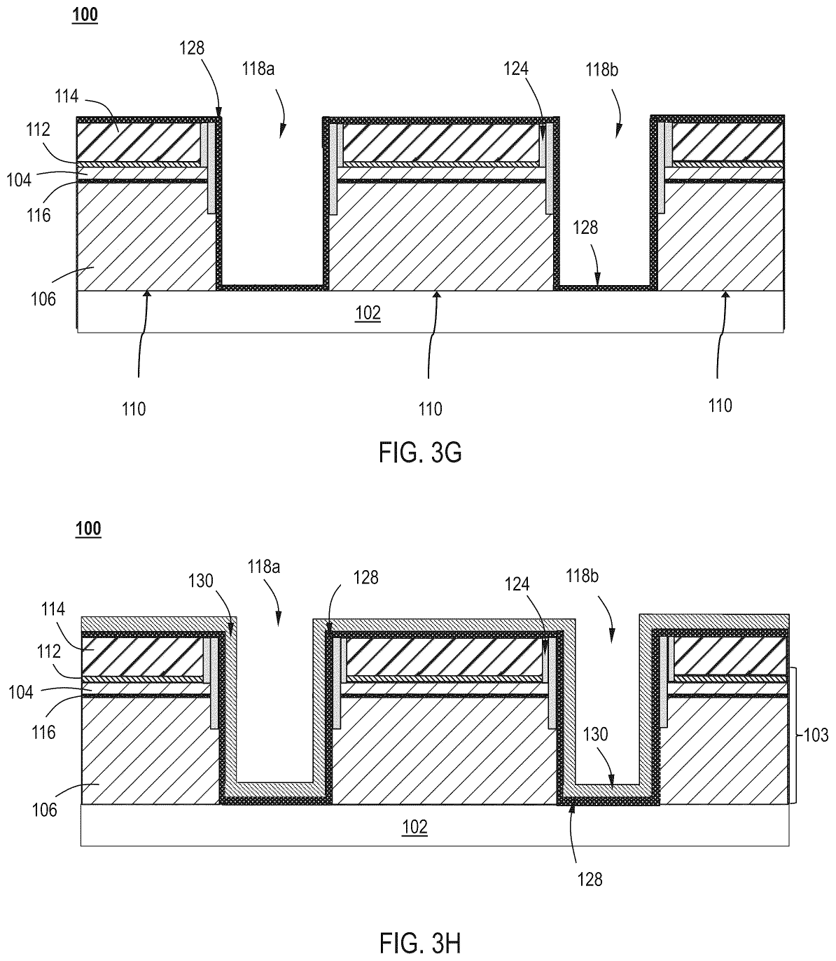

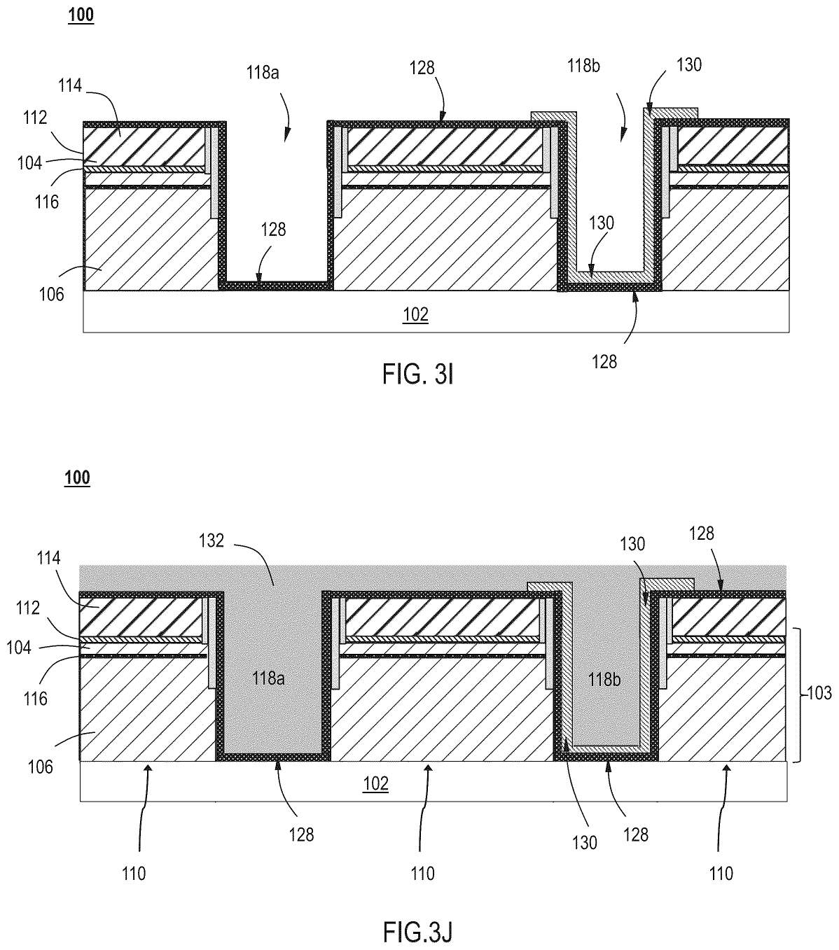

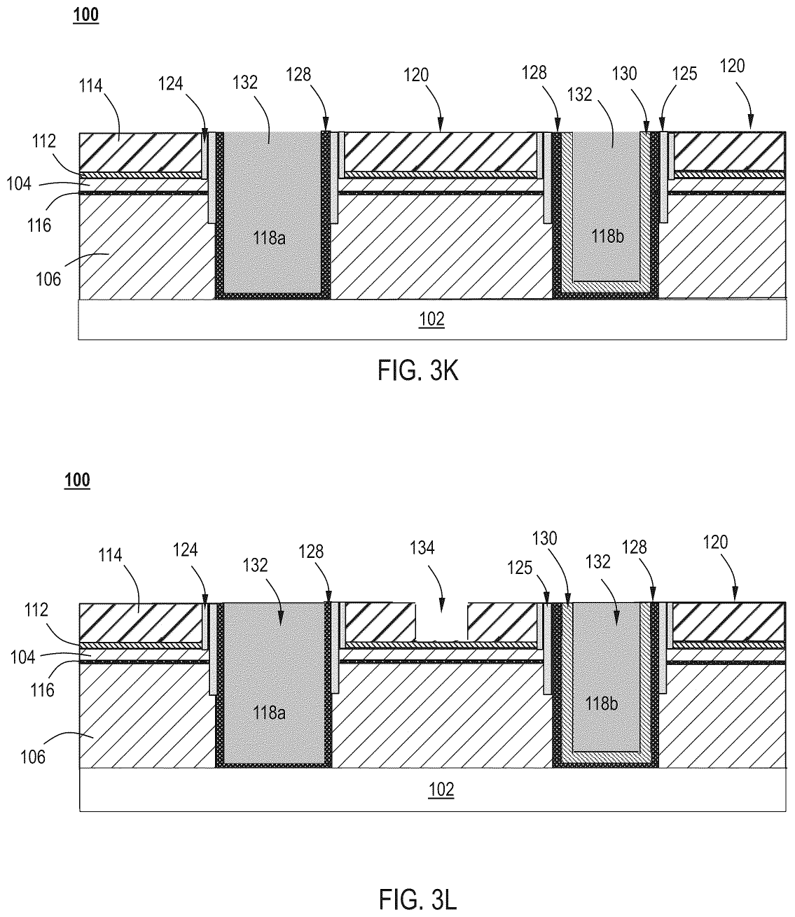

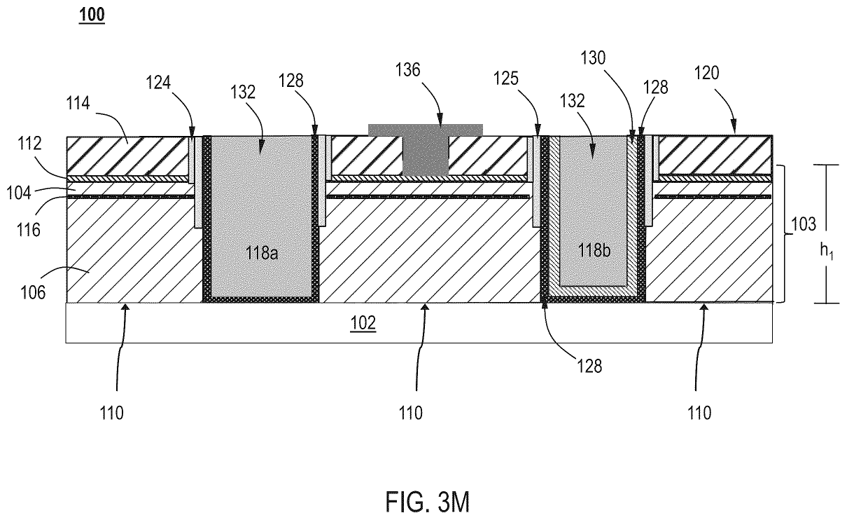

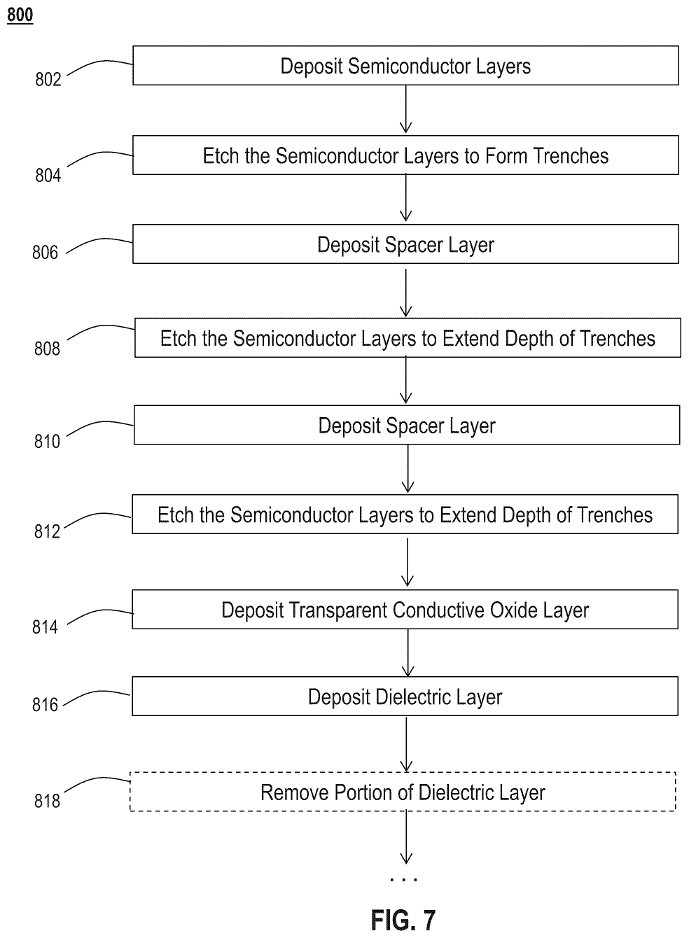

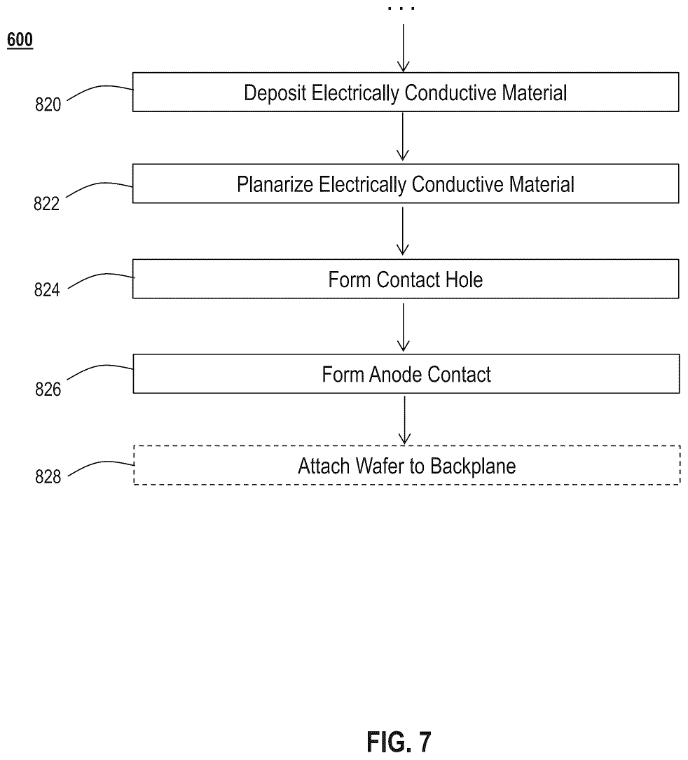

One or more embodiments of the disclosure are described with reference to the Figures. FIGS. 3A-6 illustrate various views of a device 100 according to one or more embodiments. FIG. 7 illustrates a process flow diagram of a method 800 of manufacturing an LED device according to one or more embodiments.

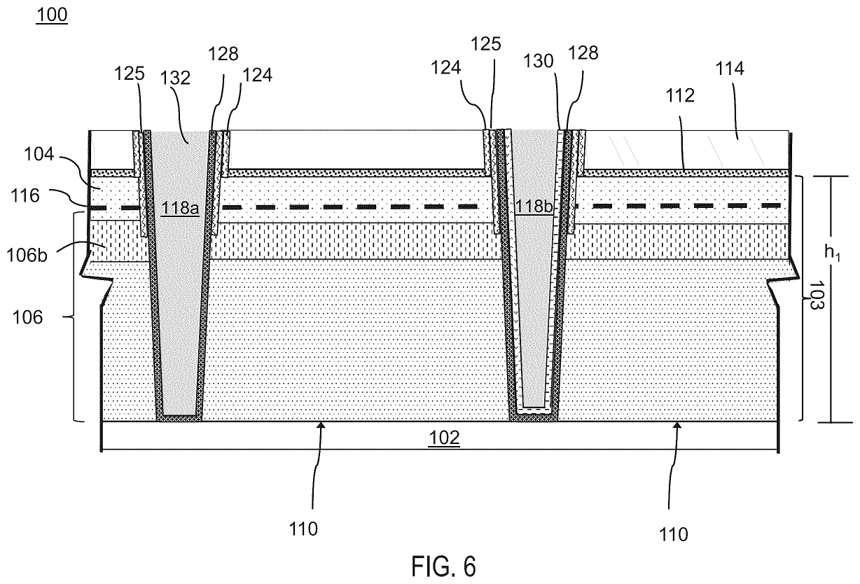

As illustrated in FIGS. 3F-3M and 6, the device 100 includes a plurality of mesas 110 comprising semiconductor layers 103 having a total height h₁. As shown, the semiconductor layers 103 include an n-type layer 106, an active region 116 and a p-type layer 104. As illustrated in FIGS. 3A-3M, the semiconductor layers 103 are disposed on a substrate 102 (which can subsequently be removed as further described herein), with the n-type layer 106 disposed on the substrate surface, the active region 116 disposed on the n-type layer 106, and the p-type layer 104 disposed on the active region 116. In one or more embodiments, the semiconductor layers 103 may be patterned or unpatterned. In the embodiments illustrated, the semiconductor layers 103 are unpatterned. One of skill in the art, however, recognizes that the semiconductor layers 103 may be patterned, as the n-type layer 14 illustrated in FIG. 2.

In one or more embodiments, the semiconductor layers 103 have a combined thickness h₁ in a range of from about 1 μm to about 10 μm, including all values and subranges therebetween, including a range of from about 1 μm to about 9 μm, 1 μm to about 8 μm, 1 μm to about 7 μm, 1 μm to about 6 μm, 1 μm to about 5 μm, 1 μm to about 4 μm, 1 μm to about 3 μm, 3 μm to about 10 μm, 3 μm to about 9 μm, 3 μm to about 8 μm, 3 μm to about 7 μm, 3 μm to about 6 μm, 3 μm to about 5 μm, 3 μm to about 4 μm, 4 μm to about 10 μm, 4 μm to about 9 μm, 4 μm to about 8 μm, 4 μm to about 7 μm, 4 μm to about 6 μm, 4 μm to about 5 μm, 5 μm to about 10 μm, 5 μm to about 9 μm, 5 μm to about 8 μm, 5 μm to about 7 μm, 5 μm to about 6 μm, 6 μm to about 10 μm, 6 μm to about 9 μm, 6 μm to about 8 μm, 6 μm to about 7 μm, 7 μm to about 10 μm, 7 μm to about 9 μm, or 7 μm to about 8 μm.

The p-type layers 104 may comprise any appropriate materials known to one of skill in the art. In one or more embodiments, the p-type layers 104 comprise gallium nitride (GaN). The active region 116 may comprise any appropriate materials known to one of skill in the art. In one or more embodiments, the active region 116 is comprised of a III-nitride material multiple quantum wells (MQW), and a III-nitride electron blocking layer. The n-type layer 106 may comprise any appropriate materials known to one of skill in the art. In one or more embodiments, the n-type layer 106 may comprise any Group III-V semiconductors, including binary, ternary, and quaternary alloys of gallium (Ga), aluminum (Al), indium (In), and nitrogen (N), also referred to as III-nitride materials. Thus, in some embodiments, the n-type layer 106 comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the n-type layer 106 comprises gallium nitride (GaN). In one or more embodiments, the n-type layer 106 is doped with n-type dopants, such as silicon (Si) or germanium (Ge). In one or more embodiments, the n-type layer 106 includes one or more portions that are doped or that may include different levels of doping, for example as illustrated by the various shaded regions within the n-type layer 106 in FIG. 6. According to one or more embodiments, the n-type layer 106 includes a highly doped n-type layer region 106b (e.g., as illustrated in FIG. 6), wherein “highly doped” refers to a doping level that is higher relative to other regions of the n-type layer 106. In one or more embodiments, one or more portions of the n-type layer 106 may be doped with one or more of silicon (Si), oxygen (O), boron (B), phosphorus (P), germanium (Ge), or manganese (Mn). It is noted that while FIGS. 3A-3M show an n-type layer 106 that does not specifically illustrate different regions of doping, it is to be understood the n-type layer 106 of FIGS. 3A-3M can include one or more portions that are doped or that may include different levels of doping. According to various embodiments, the n-type layer 106 may have a dopant concentration significant enough to carry an electric current laterally through the layer.

According to one or more embodiments, as illustrated in FIGS. 3F-3M and 6, the mesas can further include a P-contact layer 112 and a hard mask layer 114 disposed on the p-type layer 104. As shown, the P-contact layer 112 is deposited on the p-type layer 104 and the hard mask layer 114 is on the P-contact layer 112.

In one or more embodiments, the P-contact layer 112 may comprise any suitable p-metal known to the skilled artisan. In one or more embodiments, the P-contact layer 112 may comprise any suitable metal known to one of skill in the art. In one or more embodiments, the P-contact layer 112 comprises silver (Ag).

In one or more embodiments, the P-contact layer 112 may comprise a transparent conductive oxide material, such as, but not limited to indium tin oxide (ITO). In other embodiments, the P-contact layer 112 may be a composite mirror reflector layer. The composite mirror reflector layer may be made of multilayers of thin film materials of different refractive index.

In some embodiments, the P-contact layer 112 is deposited directly on the p-type layer 104. In other embodiments, not illustrated, there may be one or more additional layer between the p-type layer 104 and the P-contact layer 112. In some embodiments, the hard mask layer 114 is deposited directly on the P-contact layer 112. In other embodiments, not illustrated, there may be one or more additional layers between the hard mask layer 114 and the P-contact layer 112. The hard mask layer 114 and the P-contact layer 112 may be deposited by any appropriate technique known to the skilled artisan. In one or more embodiments, the hard mask layer 114 and P-contact layer 112 are deposited by one or more of sputter deposition, atomic layer deposition (ALD), chemical vapor deposition (CVD), physical vapor deposition (PVD), plasma enhanced atomic layer deposition (PEALD), and plasma enhanced chemical vapor deposition (PECVD).

In one or more embodiments, the hard mask layer 114 may be fabricated using materials and patterning techniques which are known in the art. In some embodiments, the hard mask layer 114 comprises a metallic or dielectric material. Suitable dielectric materials include, but are not limited to, silicon oxide (SiO), silicon nitride (SiN), silicon carbide (SiC), aluminum oxide (AlOₓ), aluminum nitride (AlN) and combinations thereof. The skilled artisan will recognize that the use of formulas like SiO, to represent silicon oxide, does not imply any particular stoichiometric relationship between the elements. The formula merely identifies the primary elements of the film.

As illustrated in FIGS. 3F-3M and 6, the device 100 further includes trenches 118a, 118b disposed between the plurality of mesas 110. The trenches 118a, 118b extend through the entire height h₁ of the semiconductor layers 103, the P-contact layer 112, and the hard mask 114. Prior to deposition of any materials or material layers within the trenches 118a, 118b, the trenches 118a, 118b include a bottom surface 123 comprising a top surface of the substrate 102 and side surfaces comprising sidewalls of the mesas 110 (e.g., a top sidewall portion formed by spacer layers 124 and a bottom sidewall portion 126 comprising a portion of the n-type layers 106, as illustrated in FIG. 3F). According to one or more embodiments, an electrically conductive material 132 is disposed within the trenches 118a, 118b, and can be deposited to fill the trenches 118a, 118b after lining the trenches 118a, 118b with one or more materials or material layers.

According to one or more embodiments, the trenches 118a, 118b are at least partially lined with an n-contact. According to one or more embodiments, the n-contact comprises a transparent conductive oxide (TCO) layer 128. According to one or more embodiments, the trenches 118a, 118b are fully lined with the n-contact (e.g., TCO layer 128), such that the n-contact is disposed (a) between the electrically conductive material 132 and the semiconductor layers 103 and (b) between the electrically conductive material 132 and the substrate 102. The n-contact (e.g., TCO layer 128) can be disposed directly on the surfaces of trenches 118a, 118b as illustrated in FIG. 3M, or one or more intermediate layers or materials (not shown) can be disposed between the n-contact and the surfaces of trenches 118a, 118b. As described further herein, according to one or more embodiments, then-contact (e.g., TCO layer 128) is substantially conformal.

According to one or more embodiments, a dielectric layer 130 is disposed on at least a portion of the n-contact within at least one trench. The dielectric layer 130 can be disposed directly on a surface of the n-contact (e.g., TCO layer 128) as illustrated in FIG. 3M, or one or more intermediate layers or materials (not shown) can be disposed between the n-contact and the dielectric layer 130. The dielectric layer 130 is disposed on one or more portions of the n-contact such that in those one or more portions, the dielectric layer 130 is disposed between the electrically conductive material 132 and the n-contact. According to one or more embodiments, the dielectric layer 130 lines the entire n-contact (e.g., TCO layer 128) within at least one trench 118b (e.g., as shown in FIG. 3M). As described further herein, according to one or more embodiments, the dielectric layer 130 lining the n-contact is substantially conformal.

According to one or more embodiments, a spacer layer 124 is disposed between the electrically conductive material 132 within the trenches 118a, 118b and an upper portion of the semiconductor layers 103. For example, the spacer layer 124 can be disposed between the electrically conductive material 132 within the trenches 118a, 118b and the p-type layer 104 and active region 116, for example as illustrated in FIG. 3M. The spacer layer 124 can further extend downward so that it is also disposed between the electrically conductive material 132 within the trenches 118a, 118b and an upper portion of the n-type layers 106, for example as illustrated in FIG. 3M. According to one or more embodiments, the spacer layer 124 is disposed between the n-contact (e.g., TCO layer 128) and an upper portion of the and the semiconductor layers 103, as illustrated in FIG. 3M.

According to one or more embodiments, a p-type contact material 136 is disposed in a surface 120 of a mesa 110. According to one or more embodiments, for example as illustrated in FIG. 3M, a p-type contact material 136 is formed in the surface 120 of the mesas 110 between trenches 118a and 118b.

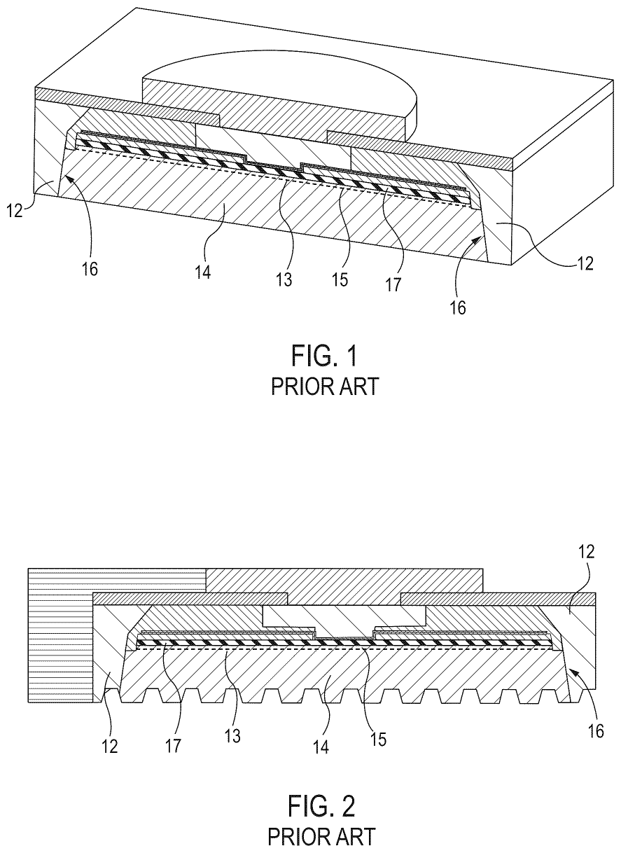

Typically, in order to electrically isolate p-type and n-type layers from metal (i.e., electrically conductive material 132 within trenches 118a, 118b between pixels), a dielectric layer (junction spacer) is used at the portion of the trench sidewalls covering the active region 116 edges, and extending to a depth sufficient to etch away the active region 116 so as to access some highly doped layers (e.g., doped N-layer) of the semiconductor layers 103. This depth corresponds to a small fraction of the semiconductor layers 103 thickness (e.g. around ⅙), as illustrated in FIGS. 1-2. Embodiments of the present disclosure provide an n-contact (e.g., TCO layer 128) disposed in at least one trench along the entire trench sidewalls and a bottom of the trench, and a dielectric layer 130 disposed on the n-contact in at least one trench along the entire trench sidewalls and a bottom of the trench. The n-contact (e.g., TCO layer 128) functions as both an n-contact and spreading layer, providing low optical absorption and optical isolation across near neighbouring pixels. By lining trenches with the n-contact and dielectric layer 130, embodiments of the disclosure further provide increased optical efficacy (Im/W).

With reference to FIG. 3A and FIG. 7, in one or more embodiments, the first part of the epitaxy (operation 802) involves the growth of an n-type layer 106 and may be the same as in a conventional LED growth run using a sapphire or other applicable growth substrate 102. The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate 102 is not patterned and can be considered to be flat or substantially flat. In other embodiments, the substrate 102 is a patterned substrate.

In one or more embodiments, the n-type layer 106 is deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein, according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein, according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similarly, to a thermal ALD process, a purge step may be conducted between the deliveries of each of the reactants.

As used herein, according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, a LED device 100 is manufactured by placing the substrate 102 in a metalorganic vapor-phase epitaxy (MOVPE) reactor so that the LED device layers are grown epitaxially.

In one or more embodiments, after the growth of the n-type layers 106, an active region 116, and p-type layers 104 are grown using deposition techniques known to one of skill in the art.

In one or more embodiments, after the growth of the active region 116 and p-type layers 104, a P-contact layer 112, and hard mask 114 are deposited using deposition techniques known to one of skill in the art.

Referring to FIG. 3B and FIG. 7, at operation 804, a plurality of openings 108a, 108b are formed. In one or more embodiments, the openings 108a, 108b may be formed using a conventional directional etching process, such as dry etching. According to one or more embodiments, the hard mask layer 114 and P-contact layer 112 are patterned to form the plurality of openings 108a, 108b in the hard mask layer 114 and P-contact layer 112, exposing a top surface of the semiconductor layers 103. According to the embodiment depicted in FIG. 3B-3F, the openings 108a, 108b may be extended in multiple operations to form mesas 110 separated by trenches 118a, 118b. For example, as depicted in FIG. 3B, a first etching operation (operation 804) may form openings 108a, 108b that extend from the top surface of the hard mask layer 114 to the n-type layers 106. According to one or more embodiments, for example as illustrated in FIG. 3B, the depth of the openings 108a, 108b extend to a top surface of the n-type layers 106. The openings 108a, 108b formed at operation 804 and illustrated in FIG. 3B may comprise at least one sidewall 121 and a bottom surface 123. In one or more embodiments, sidewalls 121 (formed at operation 804) of a first opening 108a may have a height that is about the same as the height of the sidewalls 121 of a second opening 108b (where “height” can be measured by the depth of the openings from the top surface of the hard mask layer 114). In other embodiments, the first opening 108a may have a height that is different than the height of the second opening 108b. In one or more embodiments, the sidewalls 121 may be completely vertical as illustrated in FIG. 3B or may have an angle of inclination up to 45 degrees.

In one or more embodiments, the hard mask layer 114 and P-contact layer 112 are patterned according to any appropriate patterning technique known to one of skill in the art. In one or more embodiments, the hard mask layer 114 and P-contact layer 112 are patterned by etching. According to one or more embodiments, conventional masking, wet etching and/or dry etching processes can be used to pattern the hard mask layer 114 and the P-contact layer 112.

In other embodiments, a pattern is transferred to the hard mask layer 114 and P-contact layer 112 using nanoimprint lithography. In one or more embodiments, the substrate 102 is etched in a reactive ion etching (RIE) tool using conditions that etch the hard mask layer 114 and P-contact layer 112 efficiently but etch the p-type layer 104 very slowly or not at all. In other words, the etching is selective to the hard mask layer 114 and P-contact layer 112 over the p-type layer 104. In a patterning step, it is understood that masking techniques may be used to achieve a desired pattern.

Referring to FIG. 3C and FIG. 7, at operation 806, a spacer layer 124 is deposited on the top surface of the hard mask layer 114 and sidewalls 121 of the plurality of opening 108a, 118b. According to one or more embodiments, the spacer layer 124 is deposited along the entire length of the sidewalls 121 and the entire length of the top surface of the hard mask layer 114. According to one or more embodiments, the spacer layer 124 is substantially the same thickness along its the entire length. As used herein, “substantially the same thickness” refers to a layer where the thickness is about the same throughout and varies in thickness by less than or equal to about 5%, 2%, 1% or 0.5%. The spacer layer 124 may be formed using a conventional deposition technique, such as, for example, CVD, PECVD, ALD, evaporation, sputtering, chemical solution deposition, spin-on deposition, or other like processes. Deposition of the material that forms the spacer layer 124 is typically done conformally, followed by etching to provide the spacer layer 124 on the sidewalls 121, but not on the top surface of the hard mask layer 114.

The spacer layer 124 may comprise any suitable dielectric material known to the skilled artisan. As used herein, the term “dielectric” refers to an electrical insulator material that can be polarized by an applied electric field. In one or more embodiments, the spacer layer 124 comprises a dielectric that includes, but is not limited to, oxides, e.g., silicon oxide (SiO₂), aluminum oxide (Al₂O₃), nitrides, e.g., silicon nitride (SiaN₄). In one or more embodiments, the spacer layer 124 comprises silicon nitride (SiaN₄). In other embodiments, the spacer layer 124 comprises silicon oxide (SiO₂). In some embodiments, the spacer layer 124 composition is non-stoichiometric relative to the ideal molecular formula. For example, in some embodiments, the spacer layer 124 includes, but is not limited to, oxides (e.g., silicon oxide, aluminum oxide), nitrides (e.g., silicon nitride (SiN)), oxycarbides (e.g. silicon oxycarbide (SiOC)), and oxynitrocarbides (e.g. silicon oxycarbonitride (SiNCO)). In one or more embodiments, the spacer layer 124 has a thickness greater than about 10 nm, or greater than about 20 nm, or greater than about 100 nm. In other embodiments, the spacer layer 124 has a thickness in a range of from 10 nm to 500 nm.

In some embodiments, the spacer layer 124 may be a distributed Bragg reflector (DBR). As used herein, a “distributed Bragg reflector” refers to a structure (e.g. a mirror) formed from a multilayer stack of alternating thin film materials with varying refractive index, for example high-index and low-index films.

Referring to FIG. 3D and FIG. 7, at operation 808, the plurality of openings 108a, 108b are further etched so that the openings 108a, 108b extend a further depth into the n-type layers 106. In one or more embodiments, the extension of openings 108a, 108b at operation 808 may be carried out using a conventional directional etching process, such as dry etching. As illustrated in FIG. 3D, the openings 108a, 108b now include at least one sidewall comprising a top sidewall portion formed by the spacer layer 124 and a bottom sidewall portion 126 comprising the portion of the n-type layers 106 exposed by operation 808. As further illustrated in FIG. 3D, the openings 108a, 108b now include a bottom surface 123 comprising a portion of the n-type layers 106 exposed by operation 808. In one or more embodiments, a first opening 108a formed at operation 808 may have total a height (comprising the spacer layer 124 and the bottom sidewall portion 126) that is about the same as the height of a second opening 108b. In other embodiments, the first opening 108a may have a height that is different than the height of the second opening 108b. In one or more embodiments, the sidewalls of openings 108a, 108b formed at operation 808 may be completely vertical as illustrated in FIG. 3D or may have an angle of inclination up to 45 degrees.

Referring to FIG. 3E and FIG. 7, at operation 810, an outer spacer layer 125 is deposited along the entire length of the sidewalls of openings 108a, 108b formed at operation 808. According to one or more embodiments, for example as illustrated in FIG. 3E, spacer layer material is deposited so that the resulting outer spacer layer 125 extends along the entire sidewall length from the top surface of the hard mask layer 114 to the bottom surface 123 of the openings 108a, 108b. According to one or more embodiments, similar to deposition of spacer layer 124, deposition of the material that forms the outer spacer layer 125 is typically done conformally, followed by etching to provide the outer spacer layer 125 on the sidewalls 121, but not on the top surface of the hard mask layer 114. The outer spacer layer 125 formed at operation 810 may be formed using a conventional deposition technique, such as, for example, CVD, PECVD, ALD, evaporation, sputtering, chemical solution deposition, spin-on deposition, or other like processes.

In one or more embodiments, the outer spacer layer 125 formed at operation 810 may comprise any suitable dielectric material known to the skilled artisan. In one or more embodiments, the outer spacer layer 125 comprises a dielectric that includes, but is not limited to, oxides, e.g., silicon oxide (SiO₂), aluminum oxide (Al₂O₃), nitrides, e.g., silicon nitride (Si₃N₄). In one or more embodiments, the outer spacer layer 125 comprises silicon oxide. In one or more embodiments, the outer spacer layer 125 formed at operation 810 comprises the same material as the spacer layer 124 formed at operation 806. In one or more embodiments, the spacer layer 124 has a minimum thickness greater than about 10 nm, or greater than about 20 nm, or greater than about 100 nm. In some embodiments, the outer spacer layer 125 may be a distributed Bragg reflector (DBR). In other embodiments, the outer spacer layer 125 has a thickness in a range of from about 10 nm to about 500 nm. The outer spacer layer 125 thereby provides a total internal reflection (TIR) means to increase side-wall reflectivity.

Referring to FIG. 3F and FIG. 7, at operation 812, the plurality of openings 108a, 108b are further etched to form mesas 110 separated by trenches 118a, 118b extending through the entire depth of the n-type layers 106 to a surface of the substrate 102. In one or more embodiments, extension of openings 108a, 108b at operation 812 may be carried out using a conventional directional etching process, such as dry etching. As illustrated in FIG. 3F, the trenches 118a, 118b include at least one sidewall comprising a top sidewall portion formed by the outer spacer layer 125 (formed at operation 810) and a bottom sidewall portion 126 comprising a portion of the n-type layers 106 exposed by operation 812. The trenches 118a, 118b further include a bottom surface 123 comprising a top surface of the substrate 102. In one or more embodiments, the sidewalls of trenches 118a, 118b formed at operation 812 may be completely vertical as illustrated in FIG. 3D or may have an angle of inclination up to 45 degrees.

FIG. 3G and FIG. 7, at operation 814, show formation of an n-type contact within the trenches 118a, 118b and on the top surface of the hard mask layer 114. According to one or more embodiments, the n-contact is a transparent conductive oxide (TCO) layer 128. For simplicity, when describing the device 100 and referencing the figures, the n-contact will be referred to as a TCO layer 128 in the following description. However, this is not intended to be limiting, and reference to a TCO layer 128 can be understood to refer to an n-contact generally and may be interchanged with other suitable n-contact materials. As illustrated, the TCO layer 128 lines the entire sidewalls (top sidewall portion formed by the outer spacer layer 125 and a bottom sidewall portion 126 formed at operation 812) of the trenches 118a, 118b and the bottom surface 123 (i.e., top surface of the substrate 102) of the trenches 118a, 118b. The TCO layer 128 can be fabricated of any conventional conductive oxide including, for example, indium tin oxide (ITO). The TCO layer 128 may be formed using a conventional deposition technique, such as, for example, CVD, PECVD, ALD, evaporation, sputtering, chemical solution deposition, spin-on deposition, or other like processes.

In one or more embodiments, for example, as illustrated in FIG. 3G, the TCO layer 128 is substantially conformal. As used herein, a layer which is “substantially conformal” refers to a layer where the thickness is about the same throughout (e.g., on the top surface of the hard mask layer 114, on the at least one sidewall sidewalls, including the top sidewall portion formed by the outer spacer layer 125 and a bottom sidewall portion 126 formed at operation 812, and on the bottom surface 123 of the trenches 118a, 118b). A layer which is substantially conformal varies in thickness by less than or equal to about 5%, 2%, 1% or 0.5%. In one or more embodiments, the TCO layer 128 forms on the entirety of the at least one sidewall and on the bottom surface 123 of the trenches 118a, 118b.

Referring to FIG. 3H and FIG. 7, at operation 816, show formation of a dielectric layer 130 on the TCO layer 128. The dielectric layer 130 may be formed using a conventional deposition technique, such as, for example, CVD, PECVD, ALD, evaporation, sputtering, chemical solution deposition, spin-on deposition, or other like processes. According to one or more embodiments, for example as illustrated in FIG. 3H, the dielectric layer 130 is formed directly on a surface of the TCO layer 128. However, alternate embodiments are included in which one or more intermediate layers or materials (not shown) can be disposed between the TCO layer 128 and the dielectric layer 130. According to one or more embodiments, the one or more intermediate layers or materials can suitably be selected from any conventional intermediate layers or materials.

As used herein, the term “dielectric” refers to an electrical insulator material that can be polarized by an applied electric field. In one or more embodiments, the dielectric layer 130 may comprise any suitable dielectric material known to the skilled artisan. In some embodiments, the dielectric layer 130 comprises a low-refractive index material. In some embodiments, the dielectric material comprises one of more of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ). While the term “silicon oxide” may be used to describe the dielectric layer 130, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. In one or more embodiments, the dielectric layer 130 has a thickness greater than about 300 nm, or greater than about 500 nm, or greater than about 1000 nm.

In one or more embodiments, the dielectric layer 130 is substantially conformal. As used herein, a layer which is “substantially conformal” refers to a layer where the thickness is about the same throughout and may vary in thickness by less than or equal to about 5%, 2%, 1% or 0.5%. In one or more embodiments, the dielectric layer 130 is disposed on the entirety of the TCO layer 128.

Referring to FIG. 3I and FIG. 7, at operation 818, portions of the dielectric layer 130 may be removed from the TCO layer 128. According to one or more embodiments, one or more portions of the dielectric layer 130 lining at least one trench 118a and one or more portions of the TCO layer 128 lining the top surface of the hard mask layer 114 are removed. According to one or more embodiments, for example as illustrated in FIG. 3I, after removal of portions of the dielectric layer 130 at operation 818, the dielectric layer 130 may remain disposed only on the portions of the TCO layer 128 lining the trench 118b sidewalls (i.e., top sidewall portion formed by the outer spacer layer 125 and bottom sidewall portion 126 depicted in FIG. 3F) and bottom surface 123 of the trench 118b, and portions of the TCO layer 128 disposed on the top surface of the hard mask layer 114 adjacent the trench 118b. In particular, according to one or more embodiment, the dielectric layer 130 remaining after operation 818 is a continuous layer of dielectric extending along a portion of the top surface of the hard mask layer 114 on one side of the trench 118b, along the trench 118b first sidewall, along the bottom surface 123 of the trench 118b, along the trench 118b second sidewall, and along a portion of the top surface of the hard mask layer 114 on the opposite side of the trench 118b.

The portions of the dielectric layer 130 may be removed using a conventional directional etching process, such as dry etching. In one or more embodiments, when portions of the dielectric layer 130 are removed, exposed portions of the TCO layer 128 are formed in the trench 118a and along portions of the top surface of the hard mask layer 114. According to one or more embodiments, when portions of the dielectric layer 130 are removed, the entire TCO layer 128 in the trench 118a is exposed.

Referring to FIG. 3J and FIG. 7, at operation 820, an electrically conductive material 132 is deposited. According to one or more embodiments, the electrically conductive material 132 is deposited to fill the trenches 118a, 118b and cover the exposed upper surfaces of the device 100 (e.g., exposed TCO layer 128 and exposed dielectric layer 130). The electrically conductive material 132 can suitably be selected from any conventional electrically conductive materials such as, for example, electroplated copper (Cu).

Referring to FIG. 3K and FIG. 7, at operation 822, processing is carried out to remove excess electrically conductive material 132. In one or more embodiments, the processing includes planarizing, etching, and/or polishing. As used herein, the term “planarizing” refers to a process of smoothing surfaces and includes, but is not limited to, chemical mechanical polishing/planarization (CMP), etching, and the like. According to one or more embodiments, the deposited electrically conductive material 132 is planarized to remove electrically conductive material 132 disposed outside of the trenches 118a, 118b (i.e. not disposed within the sidewalls of the trenches), and the portions of the dielectric layer 130 and TCO layer 128 disposed on the top surface of the hard mask layer 114, as illustrated in FIG. 3K. As shown in the embodiment shown by FIG. 3K, the resulting upper surface of the device 100 includes the top surface of the hard mask layer 114 surrounding the trenches 118a, 118b, upper surfaces of spacer layers 124 and outer spacer layers 125, upper surfaces of the TCO layer 128 lining trenches 118a, 118b, upper surfaces of the dielectric layer 130 lining the trench 118b, and the planarized electrically conductive material 132 disposed within the trenches 118a, 118b.

Referring to FIG. 3L and FIG. 7, at operation 824, a contact opening 134 is formed in the surface of the hard mask layer 114. According to one or more embodiments, for example as illustrated in FIG. 3L, the contact opening 134 is formed in the surface of the hard mask layer 114 between trenches 118a and 118b. The contact opening 134 can be formed by etching. In one or more embodiments, the contact opening 134 may be formed using a conventional directional etching process, such as dry etching.

Referring to FIG. 3M and FIG. 7, at operation 826, a p-type contact material 136 (or an anode contact metal) is deposited in the contact opening 134 and on a portion of the surface of the hard mask layer 114 above and to the sides of the contact opening 134. According to one or more embodiments, the p-type contact material 136 may comprise any suitable material known to the skilled artisan. In one or more embodiments, the p-type contact material 136 comprises a p-contact material selected from one or more of aluminum (Al), silver (Ag), gold (Au), platinum (Pt), and palladium (Pd). In specific embodiments, the p-type contact material 136 comprises silver (Ag). In some embodiments, additional metals may be added in small quantities to the p-type contact material 136 as adhesion promoters. Such adhesion promoters, include, but are not limited to, one or more of nickel (Ni), titanium (Ti), and chromium (Cr).

In later stages of processing, the entire device 100 or a piece of the device 100 is bonded to a system substrate such as a display backplane to form a system (e.g., FIG. 7, at operation 828). An array of landing pads may be arranged on the system substrate with dimensions aligned to those of the bonding pads on the device 100. The landing pads may be connecting to display driver circuitry in the system substrate. In one or more embodiments, after bonding, the substrate 102 is removed using a process such as laser lift-off if the substrate is a UV-transparent material such as sapphire.

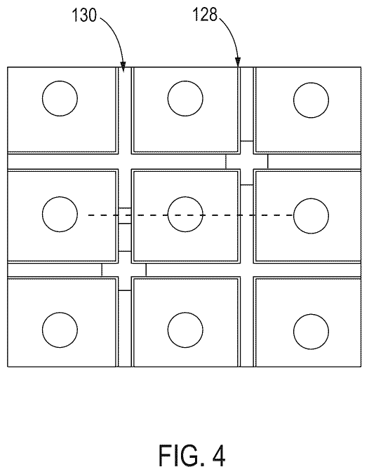

According to one or more embodiments, the disclosure provides a LED pixel die with self-aligned n-contact formation at the pixel corners, for example as illustrated in FIG. 4. Using the LED pixel die formed according to the present methods as described above, LED arrays can be provided having a variety of contact geometries, one example of which is illustrated in FIG. 4.

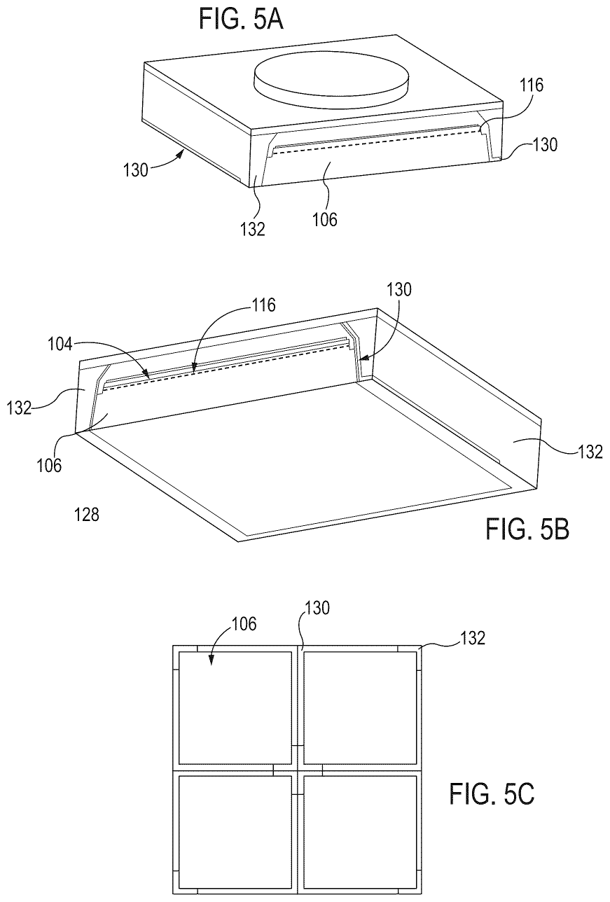

According to one or more embodiments, an LED device 100 is provided in which an electrically conductive material 132 disposed in a trench is separated from semiconductor layers 103 of a mesa 110 (N-type layer 104, an active layer 116, a P-type layer 106, a P-contact layer 112, and a hard mask layer 114). According to one or more embodiments, an n-contact (which can be a transparent conductive oxide layer 128) and a dielectric layer 130 extend between the semiconductor layers 103 and the electrically conductive material 132 along an entire length of a trench 118a/118b, for example, as illustrated in FIGS. 5A-5C. As such, the dielectric layer 130 optically isolates the trench, and the n-contact extends between the semiconductor layers 103 of the mesa and the electrically conductive material 132.

The present disclosure is in contrast with prior designs in which a metal contact 16 is formed between the trench 12 and the n-type layer 14 (as illustrated in FIGS. 1-2). The efficacy of such prior designs is severely limited by optical performance. In particular, one of the main reasons for loss of optical performance is the absorption of the trench material (i.e., metal). Without being bound by theory, it was discovered that the n-contact (metal contact 16 shown in FIG. 1) is the main contributor to loss in optical power, and an increase in efficiency can be achieved by at least partially optically isolating the trench from the semiconductor layers. According to embodiments of the disclosure, by at least partially optically isolating the trench from the semiconductor layers using the disclosed methods, materials, and structures, the ratio of lumen output (Im) to electrical power consumption (W) (i.e., Im/W) is improved. According to embodiments of the disclosure, Im/W improvements of at least about 5%, at least about 6%, at least about 7%, at least about 8%, at least about 9%, and at least about 10% are achieved by at least partially optically isolating the trench from the semiconductor layers using the disclosed methods, materials, and structures. According to embodiments of the disclosure, Im/W improvements of about 10% to about 15% are achieved by at least partially optically isolating the trench from the semiconductor layers using the disclosed methods, materials, and structures. According to embodiments of the disclosure, by at least partially optically isolating the trench from the semiconductor layers using the disclosed methods, materials, and structure, the efficiency of photo extraction from the LED is increased.

According to embodiments of the disclosure, a pixel architecture is provided in which n-contact formation is by way of a transparent conductive oxide layer 128, which spreads current from metal contact formed in a reduced area within the trench region. The present disclosure further makes it possible to optically isolate most of the trench region with the dielectric layer 130 (including a distributed Bragg Reflector DBR). As used herein, a “distributed Bragg reflector” (DBR) refers to a structure (e.g. a mirror) formed from a multilayer stack of alternating thin film materials with varying refractive index, for example high-index and low-index films. In one or more embodiments, pair of films comprise silicon dioxide (SiO₂) and titanium dioxide (TiO₂) layers. In one or more embodiments, pair of films comprise silicon dioxide (SiO₂) and niobium pentoxide (NbO₅) layers.

### Applications

LED devices disclosed herein may be monolithic arrays or matrixes. An LED device may be affixed to a backplane for use in a final application. Illumination arrays and lens systems may incorporate LED devices disclosed herein. Applications include but are not limited to beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. Light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting. Other applications include display devices.

### Display Devices

Some display devices comprise arrays and groups of LEDs or pixels, which include the embodiments disclosed herein.

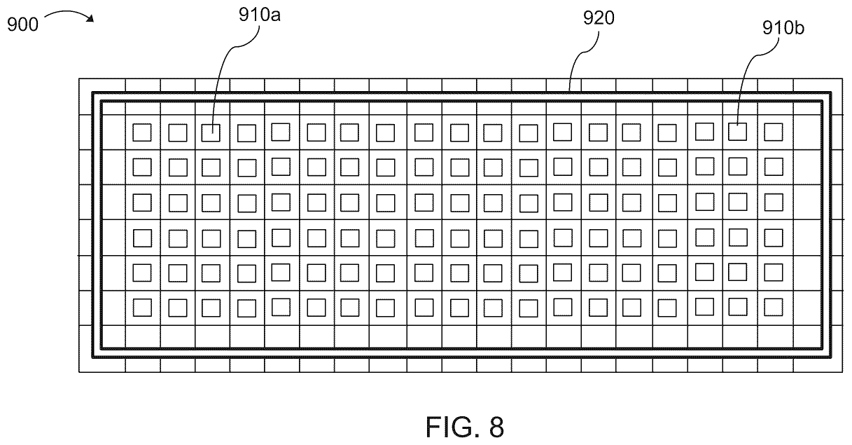

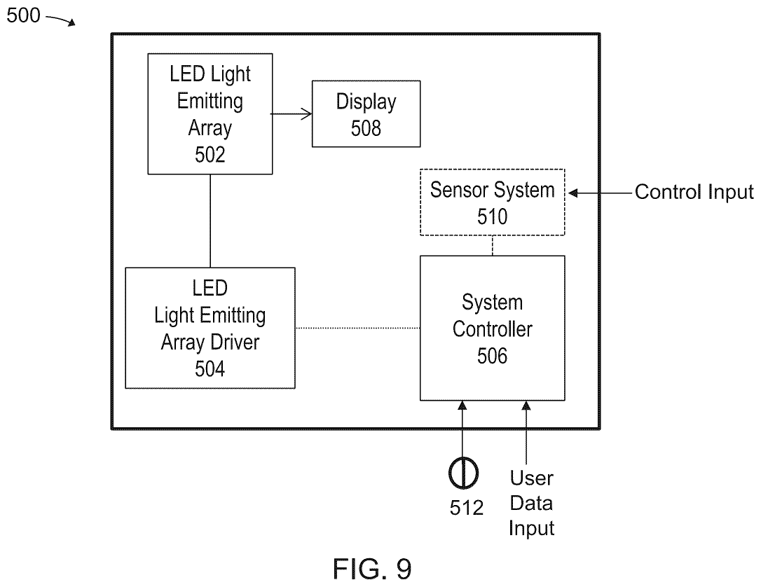

FIG. 8 shows a top plan view of an LED monolithic array 900 comprising a plurality of pixels arranged in a grid of 6×19. Pixels 910a and 910b are examples. In this embodiment, a common cathode 920 is connected to the pixels. Anodes, not shown, present on the underside are included with each pixel. In one or more embodiments, the array comprises an arrangement of 2×2 mesas, 4×4 mesas, 20×20 mesas, 50×50 mesas, 100×100 mesas, or n1×n2 mesas, where each of n1 and n2 is a number in a range of from 2 to 1000, and n1 and n2 can be equal or not equal.

In one or more embodiments, arrays of LEDs (traditional, mini-LEDs, or uLEDs) are used. In one or more embodiments, micro-LEDs can support high density pixels having a lateral dimension less than 100 μm by 100 μm. In some embodiments, micro-LEDs with dimensions of about 50 μm in diameter or width and smaller can be used. Such micro-LEDs can be used for the manufacture of color displays by aligning in close proximity micro-LEDs comprising red, blue and green wavelengths. Such micro-LEDs can be used for the manufacture of monochrome displays, such as those for automotive lighting arrangements.

In some embodiments, the light emitting arrays include small numbers of LEDs positioned on substrates that are centimeter scale area or greater. In some embodiments, the light emitting arrays include micro-LED pixel arrays with hundreds, thousands, or millions of light emitting LEDs positioned together on centimeter scale area substrates or smaller. In some embodiments, LEDs can include light emitting diodes sized between 1 microns and 500 microns. The light emitting array(s) can be monochromatic, RGB, or other desired chromaticity. In some embodiments, pixels can be square, rectangular, hexagonal, or have curved perimeter. Pixels can be of the same size, of differing sizes, or similarly sized and grouped to present larger effective pixel size.

In some embodiments, light emitting pixels and circuitry supporting light emitting arrays are packaged and optionally include a submount or printed circuit board connected for powering and controlling light production by semiconductor LEDs. In certain embodiments, a printed circuit board supporting light emitting array includes electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the light emitting array and a power supply, and also provide heat sink functionality.

FIG. 9 schematically illustrates an exemplary display system 500 utilizing LEDs disclosed herein. The display system 500 comprises an LED light emitting array 502 and display 508 in electrical communication with an LED driver 504. The display system 500 also comprises a system controller 506, such as a microprocessor. The controller 506 is coupled to the LED driver 504. The controller 506 may also be coupled to the display 508 and to optional sensor(s) 510 and be powered by power source 512. In one or more embodiments, user data input is provided to system controller 506.

Optionally sensors 510 with control input may include, for example, positional sensors (e.g., a gyroscope and/or accelerometer) and/or other sensors that may be used to determine the position, speed, and orientation of system. The signals from the sensors 510 may be supplied to the controller 506 to be used to determine the appropriate course of action of the controller 506 (e.g., which LEDs are currently illuminating a target and which LEDs will be illuminating the target a predetermined amount of time later).

In operation, illumination from some or all of the pixels of the LED array in 502 may be adjusted—deactivated, operated at full intensity, or operated at an intermediate intensity. As noted above, beam focus or steering of light emitted by the LED array can be performed electronically by activating one or more subsets of the pixels, to permit dynamic adjustment of the beam shape without moving optics or changing the focus of the lens in the lighting apparatus.

Other applications of LED arrays and devices herein include visualization systems, such as virtual reality systems and augmented reality systems and an augmented reality/virtual reality (AR/VR) systems, which may utilize any of the LEDs, including uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

According to one or more embodiments, a visualization system can include one or more light sources that can provide light for a display of the visualization system. Suitable light sources can include a light-emitting diode according to the present disclosure, a monolithic light-emitting diode according to the present disclosure, a plurality of light-emitting diodes according to the present disclosure, an array of light-emitting diodes according to the present disclosure, an array of light-emitting diodes according to the present disclosure disposed on a common substrate, a segmented light-emitting diode according to the present disclosure that is disposed on a single substrate and has light-emitting diode elements that are individually addressable and controllable (and/or controllable in groups and/or subsets), an array of micro-light-emitting diodes (microLEDs) according to the present disclosure, and others.

According to one or more embodiments, a light-emitting diode (LED) can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, which has a wavelength greater than a wavelength of the excitation light.

According to one or more embodiments, the light-emitting diode (LED) can include light-emitting diodes that emit different colors or wavelengths including, for example, red light-emitting diodes that can emit red light, a green light-emitting diodes that can emit green light, and a blue light-emitting diodes that can emit blue right. A light source can be provided that includes a red light-emitting diode, a green light-emitting diode, and a blue light-emitting diode such that the red, green, and blue light combine in specified ratios to produce any suitable color that is visually perceptible in a visible portion of the electromagnetic spectrum.

According to one or more embodiments, one or more LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. According to one or more embodiments, phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. According to one or more embodiments, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

As used herein, the term “phosphor” refers to a solid material which emits visible light when exposed to radiation from a deep blue, ultra-violet, or electron beam source. Through careful tuning of the phosphor composition and structure, the spectral content of the emitted light can be tailored to meet certain performance criteria. In some embodiments, the phosphor is selected from a ceramic phosphor plate or phosphor in silicone.

According to one or more embodiments, one or more individual pcLEDs comprise a light emitting semiconductor diode (LED) structure disposed on a substrate, and a phosphor layer (not shown) disposed on the LED. The light emitting semiconductor diode structure generally comprises an active region disposed between n-type and p-type layers. Application of a suitable forward bias across the diode structure results in emission of light from the active region. The wavelength of the emitted light is determined by the composition and structure of the active region. The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials. Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate. In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light. The individual LEDs or pcLEDs in an array may be individually operable (addressable) and/or may be operable as part of a group or subset of (e.g., adjacent) LEDs or pcLEDs in the array. Another aspect of the disclosure pertains to an electronics system. In one or more embodiments, an electronic system comprises the LED monolithic devices and arrays described herein, and driver circuitry configured to provide independent voltages to one or more of p-contact layers. In one or more embodiments, the electronic system is selected from the group consisting of a LED-based luminaire, a light emitting strip, a light emitting sheet, an optical display, and a microLED display.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light emitting diode (LED) device comprising:
a mesa comprising semiconductor layers, the semiconductor layers including an N-type layer, an active layer, and a P-type layer, the mesa having a top surface and at least one sidewall, the at least one sidewall defining a trench having a bottom surface;
an electrically conductive material disposed in the trench;
a p-type contact on the top surface of the mesa;
an n-contact disposed between the electrically conductive material in the trench and the semiconductor layers; and
an optical isolation layer disposed between the n-contact and the electrically conductive material, the optical isolation layer comprising a dielectric material;
wherein the n-contact and optical isolation layer extend along an entire length of the at least one sidewall and bottom surface of the trench.

2. The LED device of claim 1, wherein the n-contact comprises a transparent conductive oxide layer.

3. The LED device of claim 2, wherein the transparent conductive oxide layer comprises zinc oxide.

4. The LED device of claim 1, wherein the dielectric layer comprises a material selected from the group consisting of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ).

5. The LED device of claim 4, wherein the dielectric layer comprises silicon oxide.

6. The LED device of claim 1, wherein the electrically conductive material comprises one or more of silver (Ag) and aluminum (Al).

7. The LED device of claim 1, further comprising a light converting phosphor layer.

8. The LED device of claim 1, wherein the mesa further comprises a P-contact layer.

9. A light emitting diode (LED) array comprising:
a plurality of mesas defining pixels, each of the mesas comprising semiconductor layers, the semiconductor layers including an n-type layer, an active layer, and a p-type layer, each of the mesas having a top surface and sidewalls;
a plurality of trenches, each of the trenches disposed between each of the mesas, each of the trenches having a bottom surface and opposing side surfaces defining the sidewalls of the mesas;
an electrically conductive material disposed in each of the trenches;
a p-type contact on the top surface of at least one mesa;
an n-contact disposed along an entire length of the bottom surface of each of the trenches and along an entire length of the opposing side surfaces of each of the trenches, the n-contact disposed between the electrically conductive material and the semiconductor layers; and
an optical isolation layer disposed along an entire length of the n-contact in at least one trench, the optical isolation layer disposed between the electrically conductive material and the n-contact in the least one trench, the optical isolation layer comprising a dielectric material.

10. The LED array of claim 9, wherein the n-contact comprises a transparent conductive oxide layer.

11. The LED array of claim 10, wherein the transparent conductive oxide layer comprises zinc oxide.

12. The LED array of claim 9, wherein the dielectric layer comprises a material selected from the group consisting of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ).

13. The LED array of claim 12, wherein the dielectric layer comprises silicon oxide.

14. The LED device of claim 9, wherein the electrically conductive material comprises one or more of silver (Ag) and aluminum (Al).

15. The LED device of claim 9, further comprising a light converting phosphor layer.

16. The LED device of claim 9, wherein the plurality of mesas defining pixels are configured to be individually operable.

17. A display comprising: the light emitting diode (LED) array according to claim 9 affixed to a device substrate by anode metallization bumps.

18. The display of claim 17, wherein the pixels emit a single color.

19. The display of claim 18, wherein a first plurality of pixels is designed to emit a red color, a second plurality of pixels is designed to emit a blue color, and a third plurality of pixels is designed to emit a green color.

20. A method of manufacturing a light emitting diode (LED) array comprising:
depositing a plurality of semiconductor layers on a substrate, the plurality of semiconductor layers including a p-type layer disposed on the substrate, an active layer disposed on the p-type layer, and an n-type layer disposed on an active layer;
etching a portion of the semiconductor layers to form a plurality of trenches and a plurality of mesas defining a pixel, each of the mesas having a top surface and sidewalls, each of the trenches disposed between each of the mesas, each of the trenches having a bottom surface and opposing side surfaces defining the sidewalls of the mesas;
depositing an n-contact on an entire length of the bottom surface of each of the trenches and along an entire length of the opposing side surfaces of each of the trenches;
depositing a dielectric layer on an entire length of the n-contact in at least one trench;
depositing an electrically conductive material in each of the trenches; and
forming a p-type contact on the top surface of at least one mesa,
wherein the dielectric layer optically isolates the at least one trench.

21. The method of claim 20, wherein the n-contact comprises a transparent conductive oxide layer.

22. The method of claim 21, wherein the transparent conductive oxide layer comprises zinc oxide.

23. The method of claim 20, wherein the dielectric layer comprises a material selected from the group consisting of silicon nitride (SiN), titanium oxide (TiOₓ), niobium oxide (NbOₓ), aluminum oxide (AlOₓ), hafnium oxide (HfOₓ), tantalum oxide (TaOₓ), aluminum nitride (AlN), silicon oxide (SiOₓ), and hafnium-doped silicon dioxide (HfSiOₓ).

24. The method of claim 23, wherein the dielectric layer comprises silicon oxide.

25. The method of claim 20, wherein depositing the n-contact further comprises depositing the n-contact on at least a portion of the top surface of the plurality of mesas, and wherein depositing the dielectric layer further comprises depositing the dielectric layer on an entire length of the n-contact on the top surface of the plurality of mesas.

26. The method of claim 25 further comprising, prior to depositing the electrically conductive material in each of the trenches, removing at least a portion of the dielectric layer from the n-contact on the top surface of the plurality of mesas to expose a portion of the n-contact on the top surface of the plurality of mesas.

27. The method of claim 26, wherein depositing the electrically conductive material in each of the trenches further comprises depositing the electrically conductive material on the n-contact and dielectric layer on the top surface of the plurality of mesas, and the method further comprises planarizing the electrically conductive material prior to forming the p-type contact.

28. The method of claim 27, wherein planarizing the electrically conductive material removes the electrically conductive material, the transparent conductive oxide layer, and dielectric layer from the top surface of the plurality of mesas.
